(19) United States
(12) Patent Application Publication
(10) Pub. No.: US 2020/0081044 A1
(43) Pub. Date: Mar. 12, 2020

(54) POWER FLOW CALCULATION METHOD AND DEVICE FOR AC-DC INTERCONNECTED POWER SYSTEM, STORAGE MEDIUM AND TERMINAL

(71) Applicants: STATE GRID JIANGSU ELECTRIC POWER CO., LTD, Nanjing (CN); SHANDONG UNIVERSITY, Jinan (CN)

(72) Inventors: Haifeng LI, Nanjing (CN); Qing CHEN, Nanjing (CN); Xiaoming DONG, Nanjing (CN); Ming YANG, Nanjing (CN); Xiaomei YANG, Nanjing (CN); Yijun FEI, Nanjing (CN); Tao JIN, Nanjing (CN); Quan CHEN, Nanjing (CN); Haowen LIU, Nanjing (CN)

(21) Appl. No.: 16/538,673

(22) Filed: Aug. 12, 2019

(30) Foreign Application Priority Data
Sep. 7, 2018 (CN) 201811045461.5
Apr. 17, 2019 (CN) 201910309632.9

(51) Int. Cl. G01R 21/133; G01R 21/00

(52) U.S. Cl. CPC G01R 21/1331; G01R 21/003

(57) ABSTRACT

Provided are a power flow calculation method and device for an alternating current (AC)-direct current (DC) interconnected power system, a storage medium and terminal. A state of a DC network is calculated according to a control mode of a converter station, and a connection point between the DC network and an AC network is equivalent to a power node; and power flow calculation is performed through a Newton-Raphson method.

### CROSS-REFERENCES TO RELATED APPLICATIONS

This application claims priority to Chinese patent applications CN201811045461.5 filed on Sep. 7, 2018 and CN201910309632.9 field on Apr. 17, 2019, the disclosures of which are incorporated herein by reference in their entirety.

### TECHNICAL FIELD

The present disclosure relates to the field of power flow calculation in a power system and, in particular, to an alternating current (AC)-direct current (DC) hybrid a power flow calculation method and device for an AC-DC interconnected power system, a storage medium and a terminal.

### BACKGROUND

The power flow calculation is a basic calculation for research on the steady-state operation conditions of a power system. The power flow calculation can be adopted to obtain a voltage and/or power at each node of the power transmission and distribution line from electricity generation to load consumption. Currently, the power flow calculation method for an AC-DC interconnected power system mainly includes an alternating iterative method and a simultaneous solution method.

The alternating iterative method has a main advantage that an admittance matrix and a Jacobian matrix of the original nodes are unchanged in the main iteration, and merely a node power balance equation needs to be slightly modified. Therefore, the alternating iterative method is easy to be combined with the original power flow algorithm to be implemented by programming. The alternating iterative method has a disadvantage that the control variable of a new element device is merely corrected in the sub-iteration, and the value in the main iteration of the control variable is maintained unchanged as the corrected value in the sub-iteration. The difference due to the interaction of the main iteration and the sub-iteration causes a poor convergence characteristic of the whole algorithm and even numerical oscillation or divergence, so that the algorithm is not converged and no longer has the second-order convergence characteristic of the traditional Newton-Raphson method.

The simultaneous solution method has an advantage that the convergence characteristic of the traditional power flow algorithm is reserved. In the simultaneous solution method, a unified simultaneous iteration is performed to obtain a solution of an equation set of the operation state variables of the system and a solution of an equation set of the control variable of the new element, thus having the convergence characteristic of the traditional Newton-Raphson method. Compared with the original power flow calculation of the power grid, new state variables and a control target equation or an internal restriction equation are added in the simultaneous solution method, and the original Jacobian matrix needs to be modified and expanded. How to select an initial value of the new control variable needs to be considered, and the Newton-Raphson method has strong dependence on the initial value of the variable so that the simultaneous solution method also has the problems of a low convergence speed and poor convergence reliability. Meanwhile, the new control target equation and the classical power flow equation have a large difference in their expressions, which might cause a morbid correction equation.

### SUMMARY

To solve the preceding problems, embodiments of the present disclosure provide a power flow calculation method and device for an AC-DC interconnected power system, a storage medium and a terminal, to enable the problems of power flow calculation in the related art of poor convergence reliability and an easily occurred morbid correction equation to be solved.

In a first aspect, an embodiment of the present disclosure provides a power flow calculation method for an AC-DC interconnected power system. The method includes steps described below.

A conductance matrix is solved for a DC network of the AC-DC interconnected power system, and a resistance between any two of converters in the DC network is acquired, or a resistance between any two of connection points of the DC network hierarchical structures is acquired.

A DC voltage and an active power of a node corresponding to each of the converters are acquired according to a structure of the DC network.

A control mode of the each of the converters is acquired.

A reactive power injection amount of the each of the converters into an AC power grid is calculated according to the DC voltage, the active power, and the control mode of the each of the converters.

Power flow calculation is performed through a Newton-Raphson method according to the resistance between the any two of the converters or the resistance between the any two of the connection points, the DC voltage, the active power, the reactive power injection amount and the control mode of the each of the converters.

Optionally, acquiring the DC voltage and the active power of the node corresponding to the each of the converters according to the structure of the DC network includes steps described below.

A node parameter corresponding to the each of the converters is acquired according to the structure of the DC network.

According to the node parameter, an equation set is constructed:

$$\{ \begin{matrix}{I}_{dk} = {\sum }_{j = 1}^{{n}_{c}} {G}_{kj} {V}_{dj} \\ {P}_{dk} = {I}_{dk} {V}_{dk}\end{matrix} .$$

Where V_{dk} is the DC voltage of the node corresponding to the each of the converters, P_{dk} is the active power of the node corresponding to the each of the converters, and I_{dk} is a DC current flowing into a converter station k, Gₖⱼ is an admittance matrix element between a node k corresponding to the converter station k and a node j, V_{dj} is a voltage of a DC bus connected to a converter j, and n_{c} is a number of converters in the DC network.

The DC voltage and the active power of the node corresponding to the each of the converters are calculated according to the equation set.

Optionally, in condition that the DC network of the AC-DC interconnected power system includes a hierarchical structure, active power outputted by a single converter on a series side of the DC network is proportional to a voltage ratio of the single converter.

Optionally, when the DC network of the AC-DC interconnected power system includes the hierarchical structure, the following relationship is satisfied:

$$\{ \begin{matrix}{I}_{di 1} = {I}_{di 2} = {I}_{d} \\ {I}_{d} = \frac{{V}_{dr} - ( {V}_{di 1} + {V}_{di 2} )}{{R}_{d}}\end{matrix} ,$$

where I_{di1} is a current flowing through a high-voltage converter of a converter station in the hierarchical structure and I_{di2} is a current flowing through a low-voltage converter of the converter station in the hierarchical structure, I_{d} denotes a current flowing through the converter station, V_{dr} is a sending end voltage of the DC network, V_{di1} denotes a DC voltage of the high-voltage converter in the hierarchical structure and V_{di2} denotes a DC voltage of the low-voltage converter in the hierarchical structure; and R_{d} is a resistance of a DC line.

Calculating the DC voltage and the active power of the node corresponding to the each of the converters according to the equation set specifically includes: calculating the DC voltage and the active power according to the following equation set:

$$\{ \begin{matrix}{P}_{idk} = {k}_{idk} {P}_{d} \\ {V}_{idk} = {k}_{idk} {V}_{d}\end{matrix} .$$

Where k_{idk} is a voltage ratio of a converter k in the hierarchical structure, P_{d} is active power of the DC network injected into a converter station, and V_{d} is a DC voltage of a node connected to the converter station, P_{idk} is active power outputted by the converter k in the hierarchical structures, and V_{idk} is a DC voltage applied across the converter k in the hierarchical structures.

Optionally, the control mode of the each of the converters includes a first type control mode and a second type control mode.

The first type control mode comprises constant active power control mode, a constant DC voltage control mode, and a constant DC current control mode.

The second type control mode comprises a constant transformation ratio control mode and a constant overlap angle control mode.

Optionally, when the control mode of the each of the converters is the first type control mode, calculating the reactive power injection amount of the each of the converters into the AC power grid according to the DC voltage, the active power, and the control mode of the each of the converters specifically comprises calculating the reactive power injection amount according to the following equation set:

$$\{ \begin{matrix}{P}_{dk} = {I}_{dk} {V}_{dk} \\ {Q}_{dk} = {V}_{dk} {I}_{dk} tan {ϕ}_{k}\end{matrix} .$$

Where I_{dk} is a DC current flowing into a converter k, P_{dk} is the active power, V_{dk} is the DC voltage, φₖ is a power factor of the converter, and Q_{dk} is the reactive power injection amount.

Optionally, when the control mode of the each of the converters is the second type control mode, and the second control mode is the constant overlap angle control mode, calculating the reactive power injection amount of the each of the converters into the AC power grid according to the DC voltage, the active power, and the control mode of the each of the converters specifically comprises calculating the reactive power injection amount according to the following equation set:

$${Q}_{dk} = \frac{{k}_{y} {P}_{dk} ( {V}_{dk}^{2} + {P}_{idk} {X}_{C} ) \times \sqrt{1 - \frac{{V}_{dk}^{4} {cos}^{2} ( {θ}_{d} )}{{{k}_{y}^{2} ( {V}_{dk}^{2} + {P}_{idk} {X}_{C} )}^{2}}}}{{V}_{dk}^{2}} ,$$

where V_{dk} is a DC power transmission voltage, P_{dk} is active power flowing into a converter k, P_{idk} is active power of the DC network injected into an AC node i, θ_{d} is a control angle of the converter, and X_{c} is an overlap resistance, k_{y} is a converter constant, and Q_{dk} is the reactive power injection amount.

Optionally, when the control mode of the each of the converters is the second type control mode, and the second type control mode is the constant transformation ratio control mode, calculating the reactive power injection amount of the each of the converters into the AC power grid according to the DC voltage, the active power, and the control mode of the each of the converters specifically comprises calculating the reactive power injection amount according to the following equation set:

$${Q}_{dk} = \frac{{P}_{dk} \sqrt{- {V}_{dk} + {k}_{y}^{2} {k}_{T}^{2} {V}_{a}^{2}}}{{V}_{dk}} ,$$

where V_{dk} is a DC power transmission voltage, P_{dk} is active power flowing into a converter k, Vₐ is a voltage amplitude of a node connected to the converter, k_{T} is a transformation ratio, and k_{y} is a converter constant.

Optionally, performing the power flow calculation through the Newton-Raphson method according to the resistance between the any two of the converters or the resistance between the connection points, the DC voltage, the active power, the reactive power injection amount and the control mode of the each of the converters includes steps described below.

An unbalance amount of the active power and an unbalance amount of the reactive power injection amount in the power flow calculation are acquired according to the resistance between the any two of the converters or the resistance between the connection points, the DC voltage, the active power, the reactive power injection amount and the control mode of the each of the converters.

A Jacobian matrix for the power flow calculation is established according to the control mode of the each of the converters, the unbalance amount of the active power and the unbalance amount of the reactive power injection amount. When the control mode of the each of the converters is the second type control mode, and the second control mode is the constant overlap angle control mode, a Jacobian matrix parameter of the node corresponding to the each of the converters is determined merely by an AC network parameter. When the control mode of the each of the converters is the second type control mode, and the second type control mode is the constant transformation ratio control mode, the Jacobian matrix parameter of the node corresponding to the each of the converters is corrected after being determined by the AC network parameter.

The power flow calculation is performed through the Newton-Raphson method according to the Jacobian matrix.

Optionally, when the control mode of the each of the converters is the second type control mode, and the second type control mode is the constant transformation ratio control mode, performing the power flow calculation through the Newton-Raphson method according to the Jacobian matrix further includes a step described below.

An element Lii of the Jacobian matrix is corrected as follows:

$${L}_{ii} = - {V}_{i} {\sum }_{j ∈ i , j \neq i} {V}_{j} ( {G}_{ij} sin {θ}_{ij} - {B}_{ij} cos {θ}_{ij} ) + 2 {V}_{i}^{2} {B}_{ii} - \frac{{k}_{y}^{2} {k}_{T}^{2} {P}_{dk} {V}_{a}}{{V}_{dk} \sqrt{- {V}_{dk}^{2} + {k}_{y}^{2} {k}_{T}^{2} {V}_{i}^{2}}} ,$$

where i is a node of an AC network connected to the each of the converters; Vᵢ is a voltage amplitude of the node i, Gᵢⱼ and Bᵢⱼ are respectively a real part and an imaginary part of an admittance matrix, Vₐ is a voltage amplitude of a node connected to the each of the converters, V_{dk} is a DC power transmission voltage; P_{dk} is active power flowing into a converter k, k_{T} is a transformation ratio, k_{y} is a converter constant, θᵢⱼ is a control angle of the node i, H, N and L are block matrices of the Jacobian matrix, ΔP is the unbalance amount of the active power, ΔQ is the unbalance amount of the reactive power injection amount, and Δθ and ΔV are correction amounts of variables in an iterative process.

Optionally, performing the power flow calculation through the Newton-Raphson method further includes steps described below.

It is determined whether an calculation result of the power flow satisfies a convergence condition.

In condition that the calculation result of the power flow satisfies the convergence condition, the power flow calculation is completed.

In condition that the calculation result of the power flow does not satisfy the convergence condition, the unbalance amount of the active power and the unbalance amount of the reactive power injection amount in the power flow calculation are acquired again.

In a second aspect, an embodiment of the present disclosure further provides a power flow calculation device for an AC-DC interconnected power system. The device includes a resistance acquisition module, a DC voltage and active power acquisition module, a control mode acquisition module, a reactive power injection amount calculation module and a power flow calculation module.

The resistance acquisition module is configured to solve a conductance matrix for a DC network of the AC-DC interconnected power system, and acquire a resistance between any two of converters in the DC network, or acquire a resistance between any two of connection points of the DC network of hierarchical structures.

The DC voltage and active power acquisition module is configured to acquire a DC voltage and an active power of a node corresponding to each of the converters according to a structure of the DC network.

The control mode acquisition module is configured to acquire a control mode of the each of the converters.

The reactive power injection amount calculation module is configured to calculate a reactive power injection amount of the each of the converters into an AC power grid according to the DC voltage, the active power, and the control mode of the each of the converters.

The power flow calculation module is configured to perform power flow calculation through a Newton-Raphson method according to the resistance between the any two of the converters or the resistance between the connection points, a voltage of a DC bus, the active power, the reactive power injection amount and the control mode of the each of the converters.

In a third aspect, an embodiment of the present disclosure further provides a storage medium configured to store computer programs, which, when executed by a processor, implement the power flow calculation method for the AC-DC interconnected power system described above.

In a fourth aspect, an embodiment of the present disclosure further provides a terminal, including a display screen, a memory, a processor, and computer programs stored in the memory and executable by the processor, where, when executing the computer programs, the processor implements the power flow calculation method for the AC-DC interconnected power system described above.

In the power flow calculation method and device for the AC-DC interconnected power system, the storage medium and the terminal according to the embodiments of the present disclosure, the corresponding parameters are obtained by analyzing the control mode of each converter in the AC-DC interconnected power system, and the power flow calculation is performed through the Newton-Raphson method, thereby avoiding the problem that calculation is not facilitated due to a large selection scale of an initial value and a large scale of a Jacobian matrix. Therefore, the power flow calculation for the AC-DC interconnected power system has better convergence, reduced calculation complexity, an improved calculation rate, and reduced costs.

In addition, to solve the preceding problems, the present disclosure further provides an a power flow calculation method and system for an AC-DC interconnected power system having DC hierarchical structures. In the present disclosure, a connection point between a DC network and an AC network is equivalent to a power node in the AC network to so that power flow calculation has a faster convergence speed and better convergence reliability.

To achieve the preceding object, the present disclosure provides the following technical solutions:

A power flow calculation method for an AC-DC interconnected power system having DC hierarchical structures includes: calculating a state of a DC network according to a control mode of a converter station, and making a connection point between the DC network and an AC network equivalent to a power node; and performing power flow calculation through a Newton-Raphson method.

Specifically, the method includes steps described below.

A conductance matrix is solved for a DC network, and a resistance between each two of converters is acquired, or a resistance between any two of connection points of a DC power grid of a hierarchical structures is acquired.

A control mode of each of the converters is analyzed, and a voltage and active power of each node are calculated.

A reactive power injection amount into an AC power grid is calculated according to the control mode, and the voltage and the active power of the each node.

Power flow calculation is performed through a Newton-Raphson method to obtain a calculation result.

Furthermore, part of parameters of the each node is determined according to the control mode of the each of the converters, an equation set is constructed, and the voltage and the active power of the each node are calculated according to a specific equation set:

$$\begin{matrix}{I}_{di 1} = {I}_{di 2} = {I}_{d} \\ \frac{{V}_{dr} - ( {V}_{di 1} + {V}_{di 2} )}{{R}_{d}} = {I}_{d}\end{matrix} \} \qquad ( 1 )$$

where I_{di1} is a current flowing through a high-voltage converter of the converter station in the hierarchical structures and I_{di2} is a current flowing through a low-voltage converter of the converter station in the hierarchical structures, I_{d} denotes a current flowing through the converter station, V_{dr} is a sending end voltage of the DC network, V_{di1} denotes a DC voltage of the high-voltage converter in the hierarchical structures and V_{di2} denotes a DC voltage of the low-voltage converter in the hierarchical structures; and R_{d} is a resistance of a DC line.

Furthermore, active power outputted by a single converter on a series side is proportional to a voltage ratio of the single converter.

Furthermore, according to a control mode of a converter at a node, the reactive power injection amount into the AC power grid is calculated by using an equation (2) in a control mode for a constant overlap angle and using an equation (3) in control mode for a constant transformation ratio; and an active power injection amount is calculated by calculating the state of the DC network.

$$\begin{matrix}{Q}_{idc} = \frac{{k}_{y} {P}_{idc} ( {V}_{d c}^{2} + {P}_{idc} {X}_{c} ) \sqrt{1 - \frac{{V}_{dk}^{4} {cos}^{2} ( {θ}_{d} )}{{{k}_{y}^{2} ( {V}_{dk}^{2} + {P}_{idc} {X}_{c} )}^{2}}}}{{V}_{dk}^{2}} & ( 2 ) \\ {Q}_{d c} = \frac{{P}_{d c} \sqrt{- {V}_{d c} + {k}_{y}^{2} {k}_{T}^{2} {V}_{a}^{2}}}{{V}_{d c}} & ( 3 )\end{matrix}$$

Where V_{dc} is a voltage of a DC network node connected to the converter station, θ_{d} is a control angle of the converter which comprises a gating delay angle of a rectifier and an extinction advance angle of an inverter, k_{T} is a transformation ratio; X_{c} is an overlap resistance, a variable k_{y} is introduced considering an effect of an overlap angle, φᵢ is a power factor angle corresponding to active power (absorbed by the rectifier and emitted by the inverter) and reactive power absorbed by the converter from an AC system, and Vₐ is a voltage amplitude of an AC network connected to the converter.

Furthermore, when the hierarchical structures is involved, equivalence of the power node is performed according to a voltage ratio of a converter in the hierarchical structures.

Furthermore, a specific process for calculating the reactive power injection amount into the AC power grid includes steps described below.

(1) If a control mode of a converter corresponding to a node is a constant overlap angle, the reactive power injection amount is calculated by using an equation (2). Then proceed to step (3); otherwise proceed to step (2).

(2) If the control mode of the converter corresponding to the node is a constant transformation ratio, the reactive power injection amount is calculated by using an equation (3), and a derivative of the reactive power injection amount with respect to an AC voltage corresponding to the reactive power injection amount is calculated.

(3) With the hierarchical structures involved, a power effect of each layer on a connection point with the AC power grid is calculated according to the following equation set;

$$\{ \begin{matrix}{P}_{idk} = {k}_{idk} {P}_{d} \\ {V}_{idk} = {k}_{idk} {V}_{d}\end{matrix} \qquad ( 4 )$$

where k_{idk} is a voltage ratio of a converter k in the hierarchical structures, P_{d} is active power of the DC network injected into the converter station, and V_{d} is a DC voltage of a node connected to the converter station, P_{idk} is active power outputted by the converter k in the hierarchical structures, and V_{idk} is a DC voltage applied across the converter k in the hierarchical structures.

A specific process for performing the power flow calculation through the Newton-Raphson method includes steps described below.

(a) An initial value of the AC network is set and an unbalance amount of a power flow power equation is calculated.

(b) A Jacobian matrix is constructed. When the control mode of the each of the converters is a constant overlap angle, a Jacobian matrix parameter of a node corresponding to the each of the converters is determined merely by an AC network parameter. When the control mode of the each of the converters is a constant transformation ratio, the Jacobian matrix parameter of the node corresponding to the each of the converters is corrected after being determined by the AC network parameter.

(c) The AC network parameter is corrected, a convergence condition is checked, and an iteration is ended when the convergence condition is met; otherwise, proceed to step (a).

Furthermore, a correction mode is:

$${L}_{ii} = - {V}_{i} {\sum }_{j ∈ i , j \neq i} {V}_{j} ( {G}_{ij} sin {θ}_{ij} - {B}_{ij} cos {θ}_{ij} ) + 2 {V}_{i}^{2} {B}_{ii} - \frac{{k}_{y}^{2} {k}_{T}^{2} {P}_{d c} {V}_{a}}{{V}_{d c} \sqrt{- {V}_{d c}^{2} + {k}_{y}^{2} {k}_{T}^{2} {V}_{i}^{2}}} \qquad ( 5 )$$

where −V_{i j∈i, j≠i}Vⱼ(Gᵢⱼ sin θᵢⱼ−Bᵢⱼ cos θᵢⱼ)+2Vᵢ²Bᵢᵢ is a calculation formula of a Jacobian matrix element L in traditional pure AC power flow calculation; Vᵢ is a voltage amplitude of a node i; Gᵢⱼ and Bᵢⱼ are respectively a real part and an imaginary part of an admittance matrix; and Vₐ is a voltage amplitude of a node connected to the each of the converters and is numerically consistent with Vᵢ.

An AC-DC interconnected A power flow calculation system for an AC-DC interconnected power system having DC hierarchical structures is executed on a processor and configured to perform the following instructions:

A conductance matrix is solved for a DC network, and a resistance between each two of converters is acquired, or a resistance between any two of connection points of a DC power grid of hierarchical structures is acquired.

A control mode of each of the converters is analyzed, and a voltage and active power of each node are calculated.

A reactive power injection amount into an AC power grid is calculated according to the control mode, and the voltage and the active power of the each node.

Power flow calculation is performed through a Newton-Raphson method to obtain a calculation result.

Compared with the related art, the present disclosure has the following beneficial effects.

The present disclosure not only solves the problem of poor convergence due to alternate iterations in an alternating iterative method but also avoids the problems of an expanded scale of initial value selection and a Jacobian matrix in a simultaneous solution method, and has the advantages of good convergence and a small occupied memory in an iterative process.

The present disclosure modifies the existing pure AC power flow calculation programs by little and saves software update costs.

The technical idea of the present disclosure is totally applicable to power flow calculation in new network composition due to novel components of the current power grid, and is easy for related software to form standardized processing.

### BRIEF DESCRIPTION OF DRAWINGS

FIG. 1 is a flowchart of a power flow calculation method for an AC-DC interconnected power system according to an embodiment of the present disclosure;

FIG. 2 is a schematic diagram illustrating a circuit structure of a DC network of hierarchical structures according to an embodiment of the present disclosure;

FIG. 3 is a flowchart of a method for acquiring a DC voltage and active power according to an embodiment of the present disclosure;

FIG. 4 is a flowchart of a method for preforming power flow calculation through a Newton-Raphson method according to an embodiment of the present disclosure;

FIG. 5 is a flowchart of another method for preforming power flow calculation through a Newton-Raphson method according to an embodiment of the present disclosure;

FIG. 6 is a block diagram of a power flow calculation device for an AC-DC interconnected power system according to an embodiment of the present disclosure; and

FIG. 7 is a structural diagram of a terminal according to an embodiment of the present disclosure.

### DETAILED DESCRIPTION

Hereinafter the present disclosure will be further described in detail in conjunction with the drawings and embodiments. It may be understood that the specific embodiments set forth below are intended to illustrate and not to limit the present disclosure. Additionally, it is to be noted that, for ease of description, merely part, not all, of the structures related to the present disclosure are illustrated in the drawings.

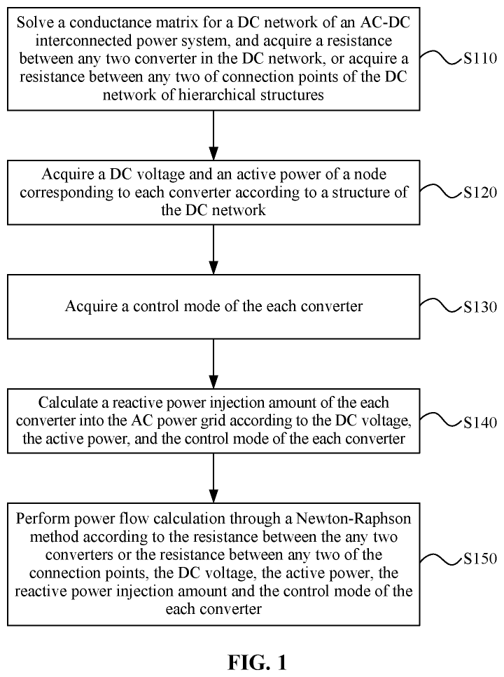

An embodiment of the present disclosure provides a power flow calculation method for an AC-DC interconnected power system, which is applicable to power flow calculation in an AC-DC interconnected power system. The AC-DC interconnected power flow calculation method according to the embodiment of the present disclosure may be executed by a power flow calculation device for the AC-DC interconnected power system which may be implemented by software and/or hardware. FIG. 1 is a flowchart of a power flow calculation method for the AC-DC interconnected power system according to an embodiment of the present disclosure. As shown in FIG. 1, the power flow calculation method for the AC-DC interconnected power system includes steps described below.

In S110, a conductance matrix is solved for a DC network of the AC-DC interconnected power system, and a resistance between any two of converters in the DC network is acquired, or a resistance between any two of connection points of the DC network of hierarchical structures is acquired.

Specifically, the AC-DC interconnected power system includes the DC network and an AC power grid. The DC network and an AC network are connected to each other through a converter. The converter may convert an AC signal in the AC power grid into a DC signal to be inputted into the DC network, and the converter may also convert the DC signal in the DC network into the AC signal to be inputted into the AC network, so that the converter of the AC-DC interconnected power system has important contribution to a stable operation of the AC-DC interconnected power system. For a multi-terminal DC network, the resistance between the any two of the converters in the DC network may be obtained by solving the conductance matrix of the DC network. Alternatively, in condition that hierarchical structures exist the DC network of the AC-DC interconnected power system, the resistance between the any two of the connection points of the DC network of the hierarchical structures may be obtained by solving the conductance matrix of the DC network.

In S120, a DC voltage and an active power of a node corresponding to each of the converters are acquired according to a structure of the DC network. Specifically, a parameter of the DC network generally includes capacitance, inductance and the like. However, when a research and an analysis are conducted on the stable operation of the AC-DC interconnected power system, merely a resistance characteristic of the DC network is generally considered, and the DC network is represented by an admittance matrix G_{d} of nodes of the DC network:

$${G}_{d} = [ \begin{matrix}{G}_{11} & ⋯ & {G}_{1 n} \\ ⋮ & ⋱ & ⋮ \\ {G}_{n 1} & ⋯ & {G}_{nn}\end{matrix} ] .$$

An injection current I_{d} of a node of the DC network may be expressed as: I_{d}=G_{d}V_{d}. Where I_{d} is the injection current of the node of the DC network, and V_{d} is an injection voltage of the node of the DC network. Accordingly, the DC voltage I_{dk} and the active power P_{dk} of the node corresponding to the each of the converters may be calculated by using the following equation set:

$$\{ \begin{matrix}{i}_{dk} = {\sum }_{j = 1}^{{n}_{c}} {G}_{kj} {V}_{dj} \\ {P}_{dk} = {I}_{dk} {V}_{dk}\end{matrix} .$$

Where V_{dk} is the DC voltage of the node corresponding to the each of the converters, P_{dk} is the active power of the node corresponding to the each of the converters, and I_{dk} is a DC current flowing into a converter station k, Gₖⱼ is an admittance matrix element between a node k corresponding to the converter station k and a node j, V_{dj} is a voltage of a DC bus connected to a converter j, and n_{c} is a number of converters in the DC network.

In addition, when the DC network of the AC-DC interconnected power system includes the hierarchical structure, active power outputted by a single converter on a series side of the DC network is proportional to a voltage ratio of the single converter. FIG. 2 is a schematic diagram illustrating a circuit structure of a DC network of a hierarchical structure according to an embodiment of the present disclosure. As shown in FIG. 2, when the DC network of the AC-DC interconnected power system includes the hierarchical structures, the injection current I_{d} of the node of the DC network should also satisfy the following relationship:

$$\{ \begin{matrix}{I}_{di 1} = {I}_{di 2} = {I}_{d} \\ {I}_{d} = \frac{{V}_{dr} - ( {V}_{di 1} + {V}_{di 2} )}{{R}_{d}} .\end{matrix}$$

Where I_{di1} is a current flowing through a high-voltage converter of a converter station in the hierarchical structures and I_{di2} is a current flowing through a low-voltage converter of the converter station in the hierarchical structures; I_{d} denotes a current flowing through the converter station; V_{dr} is a sending end voltage of the DC network; V_{di1} denotes a DC voltage of the high-voltage converter in the hierarchical structures and V_{di2} denotes a DC voltage of the low-voltage converter in the hierarchical structures; and R_{d} is a resistance of a DC line. Accordingly, a DC voltage V_{idk} and active power P_{idk} of a node corresponding to a converter i are specifically calculated as follows:

$$\{ \begin{matrix}{P}_{idk} = {k}_{idk} {P}_{d} \\ {V}_{idk} = {k}_{idk} {V}_{d}\end{matrix} .$$

Where k_{idk} is a voltage ratio of a converter k in the hierarchical structures, P_{d} is active power of the DC network injected into a converter station, and V_{d} is a DC voltage of a node connected to the converter station, P_{idk} is active power outputted by the converter k in the hierarchical structures, and V_{idk} is a DC voltage applied across the converter k in the hierarchical structures.

In S130, a control mode of the each of the converters is acquired.

Specifically, for a traditional commutated converter, each converter has two independent control variables. Assuming that a transformer tap related to the converter i may be adjusted seamlessly, a turn ratio kₜᵢ of a transformer may be linearly controlled. Therefore, active power P_{dci}, a DC voltage V_{dci} and a DC current I_{dci} of a DC bus connected to the converter i may be considered as control variables in a first type control mode, which may be defined as a D-axis control mode. A transformation ratio (turn ratio) kₜᵢ of the transformer related to the converter i and a control angle θᵢ of the converter i may be considered as control variables in a second type control mode, which may be defined as an E-axis control mode. Accordingly, the control mode of the each of the converters may be divided into the first type control mode and the second type control mode.

In S140, a reactive power injection amount of the each of the converters into the AC power grid is calculated according to the DC voltage, the active power, and the control mode of the each of the converters.

Specifically, the converters in the AC-DC interconnected power system have different control modes, and the reactive power injection amounts of the converters into the AC power grid are calculated in different manners. The control mode of the each of the converters may be divided into the first type control mode and the second type control mode. The first type control mode includes a constant active power control mode, a constant DC voltage control mode, a constant DC current control mode and the like. The second type control mode includes a constant transformation ratio control mode, a constant overlap angle control mode and the like. The overlap angle here is a determined value of the control angle of the converter.

When the control mode of the each of the converters is the first type control mode, the reactive power injection amount of the each of the converters into the AC power grid is calculated according to the DC voltage, the active power, and the control mode of the each of the converters, which is specifically preformed according to the following equation:

$$\{ \begin{matrix}{P}_{dk} = {I}_{dk} {V}_{dk} \\ {Q}_{dk} = {V}_{dk} {I}_{dk} tan {ϕ}_{k}\end{matrix} .$$

Where I_{dk} is a DC current flowing into the converter k, P_{dk} is the active power, V_{dk} is the DC voltage, φₖ is a power factor of the converter, and Q_{dk} is the reactive power injection amount.

When the control mode of the converter is the second type control mode, the equation set for calculating the reactive injection quantity needs to be combined with basic equations of the converter to calculate the reactive power injection amount. The basic equations of the converter are listed as follows:

$$\begin{matrix}{V}_{{d}^{*}} = {k}_{{T}^{*}} \times {V}_{{s}^{*}} \times cos θ d - {X}_{{C}^{*}} \times {I}_{{d}^{*}} \\ {V}_{{d}^{*}} = {k}_{y} \times {k}_{{T}^{*}} \times {V}_{{s}^{*}} \times cos ϕ \\ {I}_{{s}^{*}} = {k}_{y} \times {k}_{{T}^{*}} \times {I}_{{d}^{*}}\end{matrix} \} .$$

Where V_{d*} is a per unit of a DC power transmission voltage, I_{d*} is a per unit of a DC power transmission current, V_{s*} is a per unit of a line voltage of an AC bus, I_{s*} is a base frequency AC current injected to the converter, k_{T}* is the transformation ratio, θ_{d} is the control angle of the converter which includes a gating delay angle of a rectifier and an extinction advance angle of an inverter, φ is a power factor angle corresponding to active power (absorbed by the rectifier and emitted by the inverter) and reactive power absorbed by the converter from an AC system, X_{c*} is a per unit of an overlap resistance, and k_{y} is a converter constant which approximates 0.995 by a simplified analysis with consideration of an effect of the overlap angle.

When the control mode of the each of the converters is the second type control mode, and the second type control mode is the constant overlap angle control mode, the reactive power injection amount of the each of the converters into the AC power grid is calculated according to the DC voltage, the active power, and the control mode of the each of the converters, and the following equation is derived from the above equations:

$${Q}_{dk} = \frac{{k}_{y} {P}_{dk} ( {V}_{dk}^{2} + {P}_{idk} {X}_{C} ) \times \sqrt{1 - \frac{{V}_{dk}^{4} {cos}^{2} ( {θ}_{d} )}{{{k}_{y}^{2} ( {V}_{dk}^{2} + {P}_{idk} {X}_{C} )}^{2}}}}{{V}_{dk}^{2}}$$

Where V_{dk} is the DC power transmission voltage, P_{dk} is active power flowing into the converter k, P_{idk} is active power of the DC network injected into an AC node i, θ_{d} is the control angle of the converter, and X_{c} is the overlap resistance, k_{y} is the converter constant, and Q_{dk} is the reactive power injection amount.

When the control mode of the each of the converters is the second type control mode, and the second type control mode is the constant transformation ratio control mode, the reactive power injection amount of the each of the converters into the AC power grid is calculated according to the DC voltage, the active power, and the control mode of the each of the converters, and the following equation is derived from the above equations:

$${Q}_{dk} = \frac{{P}_{dk} \sqrt{- {V}_{dk} + {k}_{y}^{2} {k}_{T}^{2} {V}_{a}^{2}}}{{V}_{dk}} .$$

Where V_{dk} is the DC power transmission voltage, P_{dk} is the active power flowing into the converter k, Vₐ is a voltage amplitude of a node connected to the converter, k_{T} is the transformation ratio, and k_{y} is the converter constant.

In S150, power flow calculation is performed through a Newton-Raphson method according to the resistance between the any two of the converters or the resistance between the connection points, the DC voltage, the active power, the reactive power injection amount and the control mode of the each of the converters.

Specifically, when the existing Newton-Raphson method is used for performing the power flow calculation, an initial value is generally selected for performing iterative calculation, and a power flow calculation result is related to the selection of the initial value so that a large selection scale of the initial value leads to increased iteration times, and a Jacobian matrix is large in scale and is not advantageous to calculation. The power flow calculation in the AC-DC interconnected power system is performed through the Newton-Raphson method by acquiring the resistance between the any two of the converters or the resistance between the connection points and calculating the DC voltage, the active power and the reactive power injection amount according to the control mode of the each of the converters.

In the embodiments of the present disclosure, the corresponding parameters are obtained by analyzing the control mode of each converter in the AC-DC interconnected power system, and the power flow calculation is performed through the Newton-Raphson method, thereby avoiding the problem that the calculation is not facilitated due to a large selection scale of the initial value and a large scale of the Jacobian matrix. Therefore, the AC-DC interconnected power flow calculation has better convergence, reduced calculation complexity, an improved calculation rate, and reduced costs.

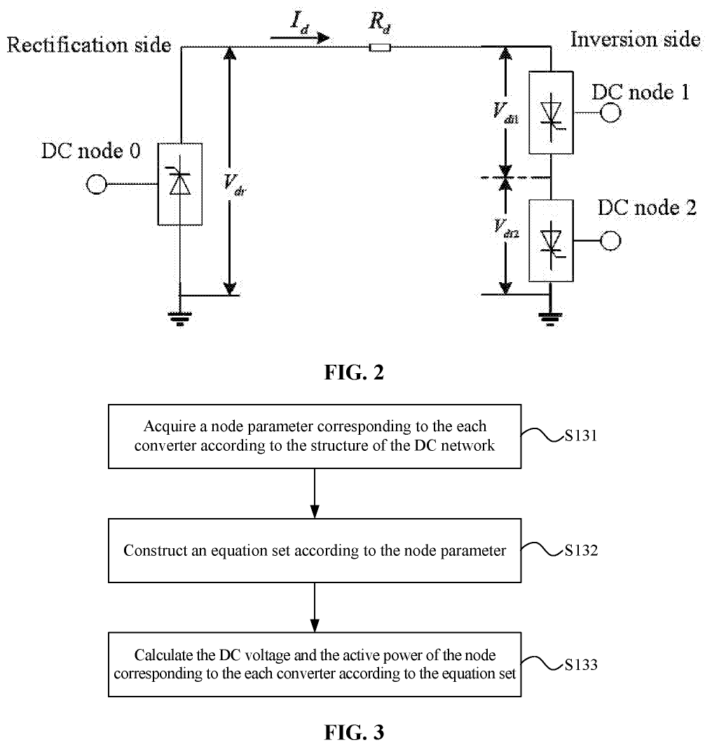

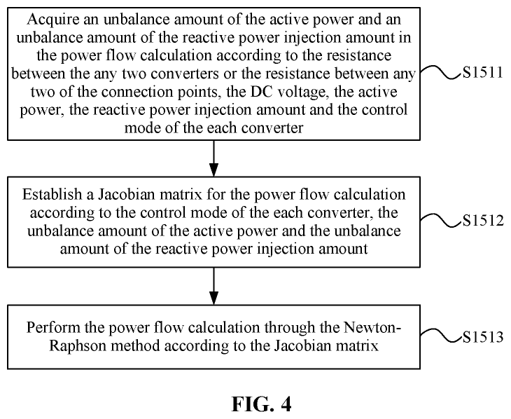

Optionally, based on the preceding embodiment, a specific method for acquiring the DC voltage and the active power is optimized. FIG. 3 is a flowchart of a method for acquiring a DC voltage and active power according to an embodiment of the present disclosure. As shown in FIG. 3, the step in which the DC voltage and the active power of the node corresponding to the each of the converters according to the structure of the DC network specifically includes steps described below.

In S131, a node parameter corresponding to the each of the converters is acquired according to the structure of the DC network.

In S132, an equation set is constructed according to the node parameter as follows:

$$\{ \begin{matrix}{I}_{dk} = {\sum }_{j = 1}^{{n}_{c}} {G}_{kj} {V}_{dj} \\ {P}_{dk} = {I}_{dk} {V}_{dk}\end{matrix} .$$

Where V_{dk} is the DC voltage of the node corresponding to the each of the converters, P_{dk} is the active power of the node corresponding to the each of the converters, and I_{dk} is the DC current flowing into the converter station k, Gₖⱼ is the admittance matrix element between the node k corresponding to the converter station k and the node j, V_{dj} is the voltage of the DC bus connected to the converter j, and n_{c} is the number of converters in the DC network.

In S133, the DC voltage and the active power of the node corresponding to the each of the converters are calculated according to the equation set.

Specifically, in condition that the DC network in the AC-DC interconnected power system has different structures, the DC voltage and the active power of the node corresponding to the each of the converters are calculated in different manners. For a converter in a general DC network, an equation set may be constructed according to the node parameter to calculate the DC voltage and the active power of the node corresponding to the converter:

$$\{ \begin{matrix}{I}_{dk} = {\sum }_{j = 1}^{{n}_{c}} {G}_{kj} {V}_{dj} \\ {P}_{dk} = {I}_{dk} {V}_{dk}\end{matrix} .$$

Therefore, the DC voltage and the active power are calculated according to the above equation set.

For the DC network of the hierarchical structures, the active power outputted by the single converter on the series side of the DC network is proportional to the voltage ratio of the single converter.

The DC voltage and the active power may be calculated according to the above equation set:

$$\{ \begin{matrix}{P}_{idk} = {k}_{idk} {P}_{d} \\ {V}_{idk} = {k}_{idk} {V}_{d}\end{matrix} .$$

Optionally, based on the preceding embodiment, a method for preforming the power flow calculation through the Newton-Raphson method is optimized. FIG. 4 is a flowchart of a method for preforming power flow calculation through a Newton-Raphson method according to an embodiment of the present disclosure. As shown in FIG. 4, the step in which the power flow calculation is performed through the Newton-Raphson method according to the resistance between the any two of the converters or the resistance between the connection points, the DC voltage, the active power, the reactive power injection amount and the control mode of the each of the converters specifically includes the steps described below.

In S1511, an unbalance amount of the active power and an unbalance amount of the reactive power injection amount in the power flow calculation are acquired according to the resistance between the any two of the converters or the resistance between the connection points, the DC voltage, the active power, the reactive power injection amount and the control mode of the each of the converters.

In S1512, a Jacobian matrix for the power flow calculation is established according to the control mode of the each of the converters, the unbalance amount of the active power and the unbalance amount of the reactive power injection amount. When the control mode of the each of the converters is the second type control mode, and the second control mode is the constant overlap angle control mode, a Jacobian matrix parameter of the node corresponding to the each of the converters is determined merely by an AC network parameter. When the control mode of the each of the converters is the second type control mode, and the second type control mode is the constant transformation ratio control mode, the Jacobian matrix parameter of the node corresponding to the each of the converters is corrected after being determined by the AC network parameter.

In S1513, the power flow calculation is performed through the Newton-Raphson method according to the Jacobian matrix.

Specifically, different converters in the AC-DC interconnected power system have different control modes, and the active power and the reactive power injection amount of a node corresponding to one converter is related to the control mode of the one converter. For example, in a general iterative process of the power flow calculation, an unbalance equation is as follows:

$$\begin{matrix}Δ {P}_{idk} = {P}_{is} - {V}_{i} {\sum }_{j = i}^{{n}_{c}} {V}_{j} ( {G}_{ij} cos {δ}_{ij} - {B}_{ij} sin {δ}_{ij} ) - ( \pm {P}_{idk} ) = 0 \\ Δ {Q}_{idk} = {Q}_{is} - {V}_{i} {\sum }_{j = i}^{{n}_{c}} {V}_{j} ( {G}_{ij} sin {δ}_{ij} - {B}_{ij} cos {δ}_{ij} ) - ( \pm {Q}_{idk} ) = 0 \\ i = {n}_{c} + k \\ k = 1 , 2 , … , {n}_{c}\end{matrix} \} .$$

Where P_{idk} and Q_{idk} are both scalars and positive values, and signs of P_{idk} and Q_{idk} are selected according to a rule that a positive sign is selected for a rectification side and a negative sign is selected for an inversion side, Pᵢₛ and Qᵢₛ are total injection power of a system generator and a load node; δᵢⱼ is a difference between phase angles of the node i and the node j, and Gᵢⱼ and Bᵢⱼ are respectively the real part and the imaginary part of the admittance matrix element.

The Jacobian matrix is constructed as follows:

$$\{ \begin{matrix}[ \begin{matrix}Δ P \\ Δ Q\end{matrix} ] = J [ \begin{matrix}Δθ \\ ΔV\end{matrix} ] \\ J = [ \begin{matrix}H & N \\ J & L\end{matrix} ]\end{matrix} ,$$

where H, N and L are block matrices of the Jacobian matrix, ΔP is the unbalance amount of the active power, ΔQ is the unbalance amount of the reactive power injection amount, and Δθ and ΔV are correction amounts of variables in an iterative process.

When the control mode of the converter corresponding to the node is the second type control mode, and the second type control mode is the constant transformation ratio control mode, the reactive power injection amount is calculated by using the following calculation formula:

$${Q}_{dk} = \frac{{P}_{dk} \sqrt{- {V}_{dk} + {k}_{y}^{2} + {k}_{T}^{2} {V}_{a}^{2}}}{{V}_{dk}}$$

At this time, the unbalance amount of the reactive power injection amount should be calculated by using the following equation:

$$\frac{{dQ}_{dk}}{{V}_{a}} = \frac{{k}_{y}^{2} {k}_{T}^{2} {P}_{dk} {V}_{a}}{{V}_{dk} \sqrt{- {V}_{dk} + {k}_{y}^{2} {k}_{T}^{2} {V}_{a}^{2}}}$$

The calculated reactive power injection amount is substituted into the Jacobian matrix, and the power flow calculation in the AC-DC interconnected power system is implemented through the Newton-Raphson method.

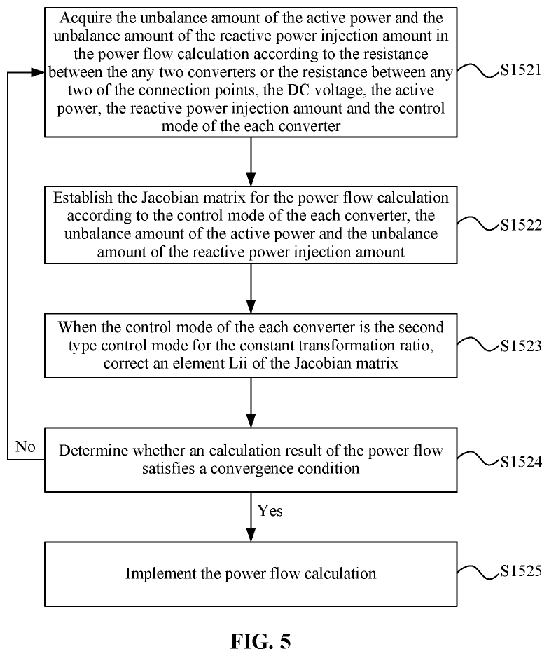

Optionally, based on the preceding embodiment, the method for preforming the power flow calculation through the Newton-Raphson method may be further optimized. FIG. 5 is a flowchart of another method for preforming power flow calculation through a Newton-Raphson method according to an embodiment of the present disclosure. As shown in FIG. 5, performing the power flow calculation through the Newton-Raphson method includes steps described below.

In S1521, the unbalance amount of the active power and the unbalance amount of the reactive power injection amount in the power flow calculation are calculated according to the resistance, the voltage of the DC bus, the active power and the reactive power injection amount.

In S1522, the Jacobian matrix for the power flow calculation is established according to the control mode of the each of the converters, the unbalance amount of the active power and the unbalance amount of the reactive power injection amount.

In S1523, when the control mode of the each of the converters is the second type control mode, and the second type control mode is the constant transformation ratio control mode, an element Lii of the Jacobian matrix is corrected.

In S1524, whether an calculation result of the power flow satisfies a convergence condition is determined. If yes, proceed to S1525. If not, proceed to S1521, and the unbalance amount of the active power and the unbalance amount of the reactive power injection amount in the power flow calculation are acquired again.

In S1525, the power flow calculation is implemented.

Specifically, the element Lii of the Jacobian matrix is calculated by using the following calculation formula:

$${L}_{ii} = - {V}_{i} {\sum }_{j ∈ i , j \neq i} {V}_{j} ( {G}_{ij} sin {θ}_{ij} - {B}_{ij} cos {θ}_{ij} ) + 2 {V}_{i}^{2} {B}_{ii} .$$

When the control mode of the each of the converters is the second type control mode, and the second type control mode is the constant transformation ratio control mode, the element Lii of the Jacobian matrix also needs to be corrected as follows:

$${L}_{ii} = - {V}_{i} {\sum }_{j ∈ i , j \neq i} {V}_{j} ( {G}_{ij} sin {θ}_{ij} - {B}_{ij} cos {θ}_{ij} ) + 2 {V}_{i}^{2} {B}_{ii} - \frac{{k}_{y}^{2} {k}_{T}^{2} {P}_{dk} {V}_{a}}{{V}_{dk} \sqrt{- {V}_{dk}^{2} + {k}_{y}^{2} {k}_{T}^{2} {V}_{i}^{2}}} ,$$

where i is a node of an AC network connected to the each of the converters; Vᵢ is a voltage amplitude of the node i, Gᵢⱼ and Bᵢⱼ are respectively a real part and an imaginary part of an admittance matrix, Vₐ is a voltage amplitude of a node connected to the each of the converters, V_{dk} is the DC power transmission voltage; P_{dk} is the active power flowing into the converter k, k_{T} is the transformation ratio, k_{y} is the converter constant, θᵢⱼ is a control angle of the node i, H, N and L are the block matrices of the Jacobian matrix, ΔP is the unbalance amount of the active power, ΔQ is the unbalance amount of the reactive power injection amount, and Δθ and ΔV are the correction amounts of the variables in the iterative process.

After the correction, the convergence of the calculation result of the power flow needs to be verified. When the calculation result of the power flow satisfies the convergence condition, the iteration process of the power flow calculation is ended and a corresponding result is outputted. When the calculation result of the power flow does not satisfy the convergence condition, the unbalance amount of the active power and the unbalance amount of the reactive power injection amount in the power flow calculation need to be calculated again until the calculation result of the power flow satisfies the convergence condition.

In the embodiments of the present disclosure, the corresponding parameters are obtained by analyzing the control mode of each converter in the AC-DC interconnected power system, and the power flow calculation is performed through the Newton-Raphson method, thereby avoiding the problem that the calculation is not facilitated due to a large selection scale of the initial value and a large scale of the Jacobian matrix. Therefore, the AC-DC interconnected power flow calculation has better convergence, reduced calculation complexity, an improved calculation rate, and reduced costs.

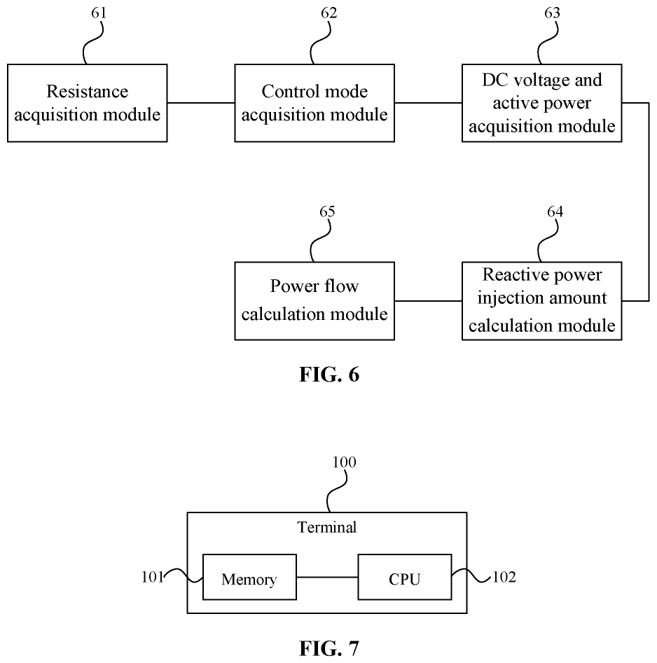

An embodiment of the present disclosure further provides a power flow calculation device for an AC-DC interconnected power system, which is applicable to power flow calculation in an AC-DC interconnected power system. The AC-DC interconnected power flow calculation device in this embodiment may be implemented by software and/or hardware. FIG. 6 is a block diagram of a power flow calculation device for an AC-DC interconnected power system according to an embodiment of the present disclosure. As shown in FIG. 6, the power flow calculation device for the AC-DC interconnected power system includes a resistance acquisition module 61, a control mode acquisition module 62, a DC voltage and active power acquisition module 63, a reactive power injection amount calculation module 64 and a power flow calculation module 65.

The resistance acquisition module 61 is configured to solve a conductance matrix for a DC network of the AC-DC interconnected power system, and acquire a resistance between any two of converters in the DC network, or acquire a resistance between any two of connection points of each hierarchical structures of the DC network.

The control mode acquisition module 62 is configured to acquire a control mode of each of the converters.

The DC voltage and active power acquisition module 63 is configured to acquire a DC voltage and active power of a node corresponding to the each of the converters according to the control mode of the each of the converters.

The reactive power injection amount calculation module 64 is configured to calculate a reactive power injection amount of the each of the converters into an AC power grid according to the DC voltage, the active power, and the control mode of the each of the converters.

The power flow calculation module 65 is configured to perform power flow calculation through a Newton-Raphson method according to the resistance between the any two of the converters or the resistance between the connection points, a voltage of a DC bus, the active power, the reactive power injection amount and the control mode of the each of the converters.

In the embodiments of the present disclosure, the corresponding parameters are obtained by analyzing the control mode of each converter in the AC-DC interconnected power system, and the power flow calculation is performed through the Newton-Raphson method, thereby avoiding the problem that the calculation is not facilitated due to a large selection scale of the initial value and a large scale of the Jacobian matrix. Therefore, the power flow calculation for the AC-DC interconnected power system has better convergence, reduced calculation complexity, an improved calculation rate, and reduced costs.

An embodiment of the present disclosure further provides a storage medium including computer-executable instructions and configured to store computer programs, which when executed by a processor, are used for implementing the power flow calculation method for the AC-DC interconnected power system according to the embodiments of the present disclosure. The method includes steps described below.

A conductance matrix is solved for a DC network of an AC-DC interconnected power system, and a resistance between any two of converters in the DC network is acquired, or a resistance between any two of connection points of each hierarchical structures of the DC network is acquired.

A DC voltage and active power of a node corresponding to each of the converters are acquired according to a structure of the DC network.

A control mode of the each of the converters is acquired.

A reactive power injection amount of the each of the converters into an AC power grid is calculated according to the DC voltage, the active power, and the control mode of the each of the converters.

Power flow calculation is performed through a Newton-Raphson method according to the resistance between the any two of the converters or the resistance between the connection points, the DC voltage, the active power, the reactive power injection amount and the control mode of the each of the converters.

The storage medium is any one of various types of memory apparatus or storage apparatus. The term “storage medium” is intended to include a mounting medium such as a compact disc read-only memory (CD-ROM), a floppy disk or a magnetic tape device; a computer system memory or a random access memory (RAM) such as a dynamic random access memory (DRAM), a double data rate (DDR) RAM, a static random access memory (SRAM), an extended data output (EDO) RAM, or a Rambus RAM; a non-volatile memory such as a flash memory or a magnetic medium (such as a hard disk or an optical storage device); a register or other similar types of memory elements, etc. The storage medium may also include other types of memory or combinations thereof. In addition, the storage medium may be located in a first computer system in which programs are executed, or may be located in a different second computer system connected to the first computer system through a network such as the Internet. The second computer system may provide program instructions to a first computer for execution. The term “storage medium” may include two or more storage media which can reside at different positions, such as in different computer systems connected through a network. The storage medium may store program instructions (e.g., embodied as computer programs) which are executable by one or more processors.

Of course, in the storage medium including the computer-executable instructions according to the embodiment of the present disclosure, the computer-executable instructions implement not only the operations of the power flow calculation method for the AC-DC interconnected power system described above but also operations related to the power flow calculation method for the AC-DC interconnected power system according to any embodiment of the present disclosure.

An embodiment of the present disclosure further provides a terminal which may integrate the power flow calculation device for the AC-DC interconnected power system according to the embodiment of the present disclosure. FIG. 7 is a structural diagram of a terminal according to an embodiment of the present disclosure. As shown in FIG. 7, the terminal may include a display (not shown), a memory 101, a central processing unit (CPU) 102 (also referred to as a processor), a circuit board (not shown) and a power circuit (not shown). The CPU 102 and the memory 101 are disposed on the circuit board. The power circuit is configured to supply each circuit or component of the terminal with power. The memory 101 is configured to store computer programs. The CPU 102 reads and executes the computer programs stored in the memory 101. When executing the computer programs, the CPU 102 implements steps described below. A conductance matrix is solved for a DC network of an AC-DC interconnected power system, and a resistance between any two of converters in the DC network is acquired, or a resistance between any two of connection points of the DC network of hierarchical structures is acquired. A DC voltage and an active power of a node corresponding to each of the converters are acquired according to a structure of the DC network. A control mode of the each of the converters is acquired. A reactive power injection amount of the each of the converters into an AC power grid is calculated according to the DC voltage, the active power, and the control mode of the each of the converters. Power flow calculation is performed through a Newton-Raphson method according to the resistance between the any two of the converters or the resistance between the connection points, the DC voltage, the active power, the reactive power injection amount and the control mode of the each of the converters.

It should be understood that the illustrated terminal 100 is merely one example of the terminal, and that the terminal 100 may include more or fewer components than the components shown in the figure, may combine two or more components, or may have a different configuration of components. The various components shown in the figure may be implemented in hardware, software, or a combination of hardware and software, which includes one or more signal processing and/or application-specific integrated circuits. The terminal 100 may be, for example, a computer.

The terminal according to the embodiment of the present disclosure implements and performs the operations of the power flow calculation method for the AC-DC interconnected power system according to any embodiment of the present disclosure, and may effectively perform the power flow calculation for the AC-DC interconnected power system.

The power flow calculation device for the AC-DC interconnected power system, the storage medium and the terminal according to the above-mentioned embodiments can execute the power flow calculation method for the AC-DC interconnected power system according to any embodiment of the present disclosure and have function modules and beneficial effects corresponding to this method. For technical details not described in detail in the above-mentioned embodiments, reference can be made to the power flow calculation method for the AC-DC interconnected power system according to any embodiment of the present disclosure.

An embodiment of the present disclosure further provides a power flow calculation method for an AC-DC interconnected power system, which is applied in DC hierarchical structures. The method includes steps described below.

In step 1, a conductance matrix is solved for a DC network, and a resistance between each two of converters is acquired, or a resistance between any two of connection points of a DC power grid of hierarchical structures is acquired.

In step 2, a control mode of each of the converters is analyzed, and a voltage and active power of each node are calculated by using the following equation:

$$\begin{matrix}{I}_{dk} = {\sum }_{j = 1}^{{n}_{c}} {G}_{kj} {V}_{dj} \\ {P}_{dk} = {I}_{dk} {V}_{dk}\end{matrix} \} , \qquad ( 6 )$$

where I_{dk} is a DC current flowing into a converter station k, and Gₖⱼ is an admittance matrix element between a node k corresponding to the converter station k and a node j.

In step 3, a reactive power injection amount into an AC power grid is calculated according to the control mode, and the voltage and the active power of the each node obtained in step 2.

Step 3 includes steps described below.

In step 3.1, in condition that a control mode of a converter corresponding to a node is a constant overlap angle control mode, the reactive power injection amount is calculated by using an equation (2).

Then proceed to step 3.3; otherwise proceed to step 3.2.

In step 3.2, in condition that the control mode of the converter corresponding to the node is a constant transformation ratio control mode, the reactive power injection amount is calculated by using an equation (3), and a derivative of the reactive power injection amount with respect to an AC voltage corresponding to the reactive power injection amount is calculated by using the following equation:

$$\frac{{dQ}_{d c}}{{V}_{a}} = \frac{{k}_{γ}^{2} {K}_{t}^{2} {P}_{d c} {V}_{a}}{{V}_{d c} \sqrt{- {V}_{d c}^{2} + {k}_{γ}^{2} {K}_{t}^{2} {V}_{a}^{2}}} . \qquad ( 7 )$$

In step 3.3, with the hierarchical structures involved, a power effect of each layer on a connection point with the AC power grid is calculated according to an equation set (4).

In step 4, power flow calculation is performed through a Newton-Raphson method.

Step 4 includes steps described below.

In step 4.1, an initial value of the AC network is set and an unbalance amount of a power flow power equation is calculated.

In step 4.2, a Jacobian matrix is constructed as the following equation set:

$$\{ \begin{matrix}[ \begin{matrix}Δ P \\ Δ Q\end{matrix} ] = J [ \begin{matrix}Δ θ \\ Δ V\end{matrix} ] \\ J = [ \begin{matrix}H & N \\ J & L\end{matrix} ]\end{matrix} , \qquad ( 8 )$$

where J is the Jacobian matrix, ΔP and ΔQ are both the unbalance amount of the power equation, and Δθ and ΔV are correction amounts of variables in an iterative process. When the control mode of the converter is the constant overlap angle, Lᵢᵢ corresponding to a node corresponding to the converter is determined merely by an AC network parameter. When the control mode of the converter is the constant transformation ratio, Lᵢᵢ corresponding to the node corresponding to the converter needs to be further corrected according to an equation (5) after being determined by the AC network parameter.

In step 4.3, the correction amounts are calculated and the AC network parameter is corrected, a convergence condition is checked, and an iteration is ended when the convergence condition is met; otherwise, proceed to step 4.1.

In step 5, a result is outputted.

Specifically, DC network modeling is described below.

(1) Traditional DC Network Model

A DC line parameter includes capacitance, inductance and the like. However, a stable operation is considered for the power flow calculation, and thus the DC line as a whole exhibits a resistance characteristic. The DC network is represented by an admittance matrix G_{d} of nodes as:

$${G}_{d} = [ \begin{matrix}{G}_{11} & {G}_{12} & ⋯ & {G}_{1 n} \\ {G}_{12} & {G}_{22} & ⋯ & {G}_{2 n} \\ ⋮ & ⋮ & ⋱ & ⋮ \\ {G}_{n 1} & {G}_{n 2} & ⋯ & {G}_{nn}\end{matrix} ] .$$

An injection current of a node may be expressed as: I_{d}=G_{d}V_{d} Where I_{d} is an injection current of a DC node, and V_{d} is a DC voltage.

Basic equations of the converter are listed as follows:

$$\begin{matrix}{V}_{{d}^{*}} = {k}_{{T}^{*}} {V}_{{s}^{*}} cos {θ}_{d} - {X}_{{c}^{*}} {I}_{{d}^{*}} \\ {V}_{{d}^{*}} = {k}_{γ} {k}_{{T}^{*}} {V}_{{s}^{*}} cos ϕ \\ {I}_{{s}^{*}} = {k}_{γ} {k}_{{T}^{*}} {I}_{{d}^{*}}\end{matrix} \} \qquad ( 9 )$$

where a mark * denotes a per unit value, V_{dci} is a DC power transmission voltage, I_{dci} is a DC power transmission current, Vᵢ∠δₛᵢ is a vector of a line voltage of an AC bus, I_{ci} is a base frequency AC current injected to the converter, nᵢᵢ is a number of bridges included in the converter, k_{Ti} is a transformation ratio, θᵢ is a control angle of the converter which includes a gating delay angle of a rectifier and an extinction advance angle of an inverter, X_{ci} is an overlap resistance, k_{γ}=0.995 by a simplified analysis with consideration of an effect of an overlap angle, φ is a power factor angle corresponding to active power (absorbed by the rectifier and emitted by the inverter) and reactive power absorbed by the converter from an AC system.

(2) DC Hierarchical Structures Involved

A simple DC power transmission structure in a layered access manner is shown in FIG. 2.

Series coupling exists between DC power transmission nodes in the layered access manner. A DC node 1 and a DC node 2 shown in FIG. 2 satisfy the following relationship:

$$\begin{matrix}{I}_{di 1} = {I}_{di 2} = {I}_{d} \\ \frac{{V}_{dr} - ( {V}_{di 1} + {V}_{di 2} )}{{R}_{d}} = {I}_{d}\end{matrix} \} .$$

Meanings of variables are consistent with those in an equation set (1).

The active power outputted by a single converter on a series side is proportional to a voltage ratio of the single converter, that is,

$$\{ \begin{matrix}{P}_{idk} = {k}_{idk} • {P}_{d} \\ {V}_{idk} = {k}_{idk} • {V}_{d}\end{matrix}$$

where k_{idk} is a voltage ratio of a converter k in the hierarchical structures, P_{d} is active power of the DC network injected into a converter station, and V_{d} is a DC voltage of a node connected to the converter station, P_{idk} is active power outputted by the converter k in the hierarchical structures, and V_{idk} is a DC voltage applied across the converter k in the hierarchical structures.

(3) Control Strategy of the Converter Station

For a traditional commutated converter, each converter has two independent control variables. Assuming that a transformer tap may be adjusted seamlessly, a turn ratio k_{T} may be linearly controlled. Therefore, active power P_{dc}, a DC voltage V_{dc} and a DC current I_{dc} of a DC bus are defined as D-axis control variables; and the transformation ratio k_{T} and the control angle θ of the converter are referred to as E-axis control variables.

TABLE 1
Control strategy of the converter

| D-axis Control | E-axis Control |
|---|---|
| Constant P_{dc} | Constant k_{T} |
| Constant V_{dc} | Constant θ |
| Constant I_{dc} | |

As for the D-axis control, in the DC network, the D-axis control of the converter at one end must be a voltage control mode, and no matter whether the D-axis control of the converters at other ends is constant P_{dc} or constant I_{dc}, Gₖⱼ is obtained with a resistance of the DC network known, and then the voltage and the active power of the converter at each end are calculated according to an equation set (6).

The E-axis control includes two types of control.

\textcircled{1} The constant overlap angle is selected for the converter.

Output power may be expressed as:

$$\begin{matrix}{P}_{idc} = {V}_{dk} {I}_{dk} \\ {Q}_{idc} = {V}_{dk} {I}_{dk} tg {ϕ}_{k}\end{matrix} \} , \qquad ( 10 )$$

where φₖ is a power factor of the converter, and V_{dk} and I_{dk} are respectively a voltage and a current of a DC node connected to the converter.

An equation set (10) is combined with an equation set (9) to obtain the following equation:

$${Q}_{idc} = \frac{{k}_{γ} {P}_{idc} ( {V}_{dk}^{2} + {P}_{idc} {X}_{c} ) \sqrt{1 - \frac{{V}_{dk}^{4} {cos}^{2} ( {θ}_{d} )}{{{k}_{γ}^{2} ( {V}_{dk}^{2} + {P}_{idc} {X}_{c} )}^{2}}} sec ( {θ}_{d} )}{{V}_{dk}^{2}} .$$

\textcircled{2} The constant transformation ratio is selected for the converter.

The equation set (10) is combined with the equation set (9) to obtain the following equation:

$${Q}_{d c} = \frac{{P}_{d c} \sqrt{- {V}_{d c}^{2} + {k}_{γ}^{2} {K}_{t}^{2} {V}_{a}^{2}}}{{V}_{d c}} .$$

3. Power Flow Calculation

In the iterative process of the power flow calculation, an unbalance equation is as follows:

$$\begin{matrix}Δ {P}_{idc} = {P}_{is} - {V}_{i} {\sum }_{j = 1}^{n} {V}_{j} ( {G}_{ij} cos {δ}_{ij} + {B}_{ij} sin {δ}_{ij} ) - ( \pm {P}_{idc} ) = 0 \\ Δ {Q}_{idc} = {Q}_{is} - {V}_{i} {\sum }_{j = 1}^{n} {V}_{j} ( {G}_{ij} sin {δ}_{ij} - {B}_{ij} cos {δ}_{ij} ) - ( {Q}_{idc} ) = 0 \\ i = {n}_{a} + k \\ k = 1 , 2 , ⋯ , {n}_{c}\end{matrix} \} \qquad ( 11 )$$

where P_{idc} and Q_{idc} are both scalars and positive values, and signs of P_{idc} and Q_{idc} are selected according to a rule that a positive sign is selected for a rectification side and a negative sign is selected for an inversion side; Pᵢₛ and Qᵢₛ are total injection power of a system generator and a load node; δᵢⱼ is a difference between phase angles of the node i and the node j; and Gᵢⱼ and Bᵢⱼ are respectively a real part and an imaginary part of an admittance matrix element.

(1) When the constant overlap angle is selected for the E-axis control of the converter, no change is needed for the original Jacobian matrix used for the power flow calculation.

(2) When the constant transformation ratio is selected for the E-axis control of the converter,

$$\frac{{dQ}_{d c}}{{V}_{a}} = \frac{{k}_{γ}^{2} {K}_{t}^{2} {P}_{d c} {V}_{a}}{{V}_{d c} \sqrt{- {V}_{d c}^{2} + {k}_{γ}^{2} {K}_{t}^{2} {V}_{a}^{2}}} .$$

In the iterative process of the power flow calculation, the unbalance amounts are consistent with those in an equation set (11).

The Jacobian matrix is modified as follows:

$${L}_{ii} = - {V}_{i} {\sum }_{j ∈ i , j \neq i} {V}_{j} ( {G}_{ij} sin {θ}_{ij} - {B}_{ij} cos {θ}_{ij} ) + 2 {V}_{i}^{2} {B}_{ii} - \frac{{k}_{γ}^{2} {K}_{t}^{2} {P}_{d c} {V}_{a}}{{V}_{d c} \sqrt{- {V}_{d c}^{2} + {k}_{γ}^{2} {K}_{t}^{2} {V}_{i}^{2}}} ,$$

where i is an AC node connected to the converter,

$$- {V}_{i} {\sum }_{j ∈ i , j \neq i} {V}_{j} ( {G}_{ij} sin {θ}_{ij} - {B}_{ij} cos {θ}_{ij} ) + 2 {V}_{i}^{2} {B}_{ii}$$

is a calculation formula of a Jacobian matrix element L in traditional pure AC power flow calculation; Vᵢ is a voltage amplitude of the node; Gᵢⱼ and Bᵢⱼ are respectively a real part and an imaginary part of an admittance matrix; and Vₐ is a voltage amplitude of a node connected to the converter and is numerically consistent with Vᵢ.

It is to be noted that the above are merely preferred embodiments of the present disclosure and the technical principles used therein. It will be understood by those skilled in the art that the present disclosure is not limited to the specific embodiments described herein. Those skilled in the art can make various apparent modifications, adaptations, combinations and substitutions without departing from the scope of the present disclosure. Therefore, while the present disclosure has been described in detail through the above-mentioned embodiments, the present disclosure is not limited to the above-mentioned embodiments and may include more other equivalent embodiments without departing from the concept of the present disclosure. The scope of the present disclosure is determined by the scope of the appended claims.

What is claimed is:

1. A power flow calculation method for an alternating current (AC)-direct current (DC) interconnected system, comprising:
solving a conductance matrix for a DC network of the AC-DC interconnected power system, and acquiring a resistance between any two of converters in the DC network, or acquiring a resistance between any two of connection points of the DC network of hierarchical structures;
acquiring a DC voltage and an active power of a node corresponding to each of the converters according to a structure of the DC network;
acquiring a control mode of the each of the converters;
calculating a reactive power injection amount of the each of the converters into an AC power grid according to the DC voltage, the active power, and the control mode of the each of the converters; and
performing power flow calculation through a Newton-Raphson method according to the resistance between the any two of the converters or the resistance between the any two of the connection points, the DC voltage, the active power, the reactive power injection amount and the control mode of the each of the converters.

2. The method of claim 1, wherein the acquiring the DC voltage and the active power of the node corresponding to the each of the converters according to the structure of the DC network comprises:
acquiring a node parameter corresponding to the each of the converters according to the structure of the DC network;
constructing, according to the node parameter, an equation set:
$$\{ \begin{matrix}{I}_{dk} = {\sum }_{j = 1}^{{n}_{c}} {G}_{kj} {V}_{dj} \\ {P}_{dk} = {I}_{dk} {V}_{dk}\end{matrix} ,$$
wherein V_{dk} is the DC voltage of the node corresponding to the each of the converters, P_{dk} is the active power of the node corresponding to the each of the converters, and I_{dk} is a DC current flowing into a converter station k, Gₖⱼ is an admittance matrix element between a node k corresponding to the converter station k and a node j, V_{dj} is a voltage of a DC bus connected to a converter j, and n_{c} is a number of converters in the DC network; and
calculating the DC voltage and the active power of the node corresponding to the each of the converters according to the equation set.

3. The method of claim 2, wherein in condition that the DC network of the AC-DC interconnected power system comprises a hierarchical structure, active power outputted by a single converter on a series side of the DC network is proportional to a voltage ratio of the single converter.

4. The method of claim 3, wherein in condition that the DC network of the AC-DC interconnected power system comprises the hierarchical structure, the following relationship is satisfied:
$$\{ \begin{matrix}{I}_{di 1} = {I}_{di 2} = {I}_{d} \\ {I}_{d} = \frac{{V}_{dr} - ( {V}_{di 1} + {V}_{di 2} )}{{R}_{d}}\end{matrix} ;$$
wherein I_{di1} is a current flowing through a high-voltage converter of a converter station in the hierarchical structure and I_{di2} is a current flowing through a low-voltage converter of the converter station in the hierarchical structure, I_{d} denotes a current flowing through the converter station, V_{dr} is a sending end voltage of the DC network, V_{di1} denotes a DC voltage of the high-voltage converter in the hierarchical structure and V_{di2} denotes a DC voltage of the low-voltage converter in the hierarchical structure, and R_{d} is a resistance of a DC line; and
wherein the calculating the DC voltage and the active power of the node corresponding to the each of the converters according to the equation set specifically comprises: calculating the DC voltage and the active power according to the following equation set:
$$\{ \begin{matrix}{P}_{idk} = {k}_{idk} {P}_{d} \\ {V}_{idk} = {k}_{idk} {V}_{d}\end{matrix} ;$$
wherein k_{idk} is a voltage ratio of a converter k in the hierarchical structure, P_{d} is active power of the DC network injected into a converter station, and V_{d} is a DC voltage of a node connected to the converter station, P_{idk} is active power outputted by the converter k in the hierarchical structure, and V_{idk} is a DC voltage applied across the converter k in the hierarchical structure.

5. The method of claim 1, wherein the control mode of the each of the converters comprises a first type control mode and a second type control mode; wherein
the first type control mode comprises constant active power control mode, a constant DC voltage control mode, and a constant DC current control mode; and
the second type control mode comprises a constant transformation ratio control mode and a constant overlap angle control mode.

6. The method of claim 5, wherein in condition that the control mode of the each of the converters is the first type control mode, the calculating the reactive power injection amount of the each of the converters into the AC power grid according to the DC voltage, the active power, and the control mode of the each of the converters comprises calculating the reactive power injection amount according to the following equation set:
$$\{ \begin{matrix}{P}_{dk} = {I}_{dk} {V}_{dk} \\ {Q}_{dk} = {V}_{dk} {I}_{dk} tan {ϕ}_{k}\end{matrix} ,$$
wherein I_{dk} is a DC current flowing into a converter k, P_{dk} is the active power, V_{dk} is the DC voltage, φₖ is a power factor of the converter k, and Q_{dk} is the reactive power injection amount.

7. The method of claim 5, wherein in condition that the control mode of the each of the converters is the second type control mode and the second type control mode is the constant overlap angle control mode, the calculating the reactive power injection amount of the each of the converters into the AC power grid according to the DC voltage, the active power, and the control mode of the each of the converters specifically comprises calculating the reactive power injection amount according to the following equation:
$${Q}_{dk} = \frac{{k}_{y} {P}_{dk} ( {V}_{dk}^{2} + {P}_{idk} {X}_{c} ) \sqrt{1 - \frac{{V}_{dk}^{4} {cos}^{2} ( {θ}_{d} )}{{{k}_{y}^{2} ( {V}_{dk}^{2} + {P}_{idk} {X}_{c} )}^{2}}}}{{V}_{dk}^{2}} ,$$
wherein V_{dk} is a DC power transmission voltage, P_{dk} is active power flowing into a converter k, P_{idk} is active power of the DC network injected into an AC node i, θ_{d} is a control angle of the converter, and X_{c} is an overlap resistance, k_{y} is a converter constant, and Q_{dk} is the reactive power injection amount.

8. The method of claim 5, wherein in condition that the control mode of the each of the converters is the second type control mode and the second type control mode is the constant transformation ratio mode, the calculating the reactive power injection amount of the each of the converters into the AC power grid according to the DC voltage, the active power, and the control mode of the each of the converters specifically comprises calculating the reactive power injection amount according to the following equation:
$${Q}_{dk} = \frac{{P}_{dk} \sqrt{- {V}_{dk} + {k}_{y}^{2} {k}_{T}^{2} {V}_{a}^{2}}}{{V}_{dk}}$$
wherein V_{dk} is a DC power transmission voltage, P_{dk} is a active power flowing into a converter k, Vₐ is a voltage amplitude of a node connected to the converter, k_{T} is a transformation ratio, and k_{y} is a converter constant.

9. The method of claim 5, wherein the performing the power flow calculation through the Newton-Raphson method according to the resistance between the any two of the converters or the resistance between the any two of the connection points, the DC voltage, the active power, the reactive power injection amount and the control mode of the each of the converters comprises:
acquiring an unbalance amount of the active power and an unbalance amount of the reactive power injection amount in the power flow calculation according to the resistance between the any two of the converters or the resistance between the any two of the connection points, the DC voltage, the active power, the reactive power injection amount and the control mode of the each of the converters;
establishing a Jacobian matrix for the power flow calculation according to the control mode of the each of the converters, the unbalance amount of the active power and the unbalance amount of the reactive power injection amount, wherein in condition that the control mode of the each of the converters is the second type control mode and the second type control mode is the constant overlap angle control mode, a Jacobian matrix parameter of the node corresponding to the each of the converters is determined merely by an AC network parameter, and in condition that the control mode of the each of the converters is the second type control mode and the second type control mode is the constant transformation ratio control mode, the Jacobian matrix parameter of the node corresponding to the each of the converters is corrected after being determined by the AC network parameter; and
performing the power flow calculation through the Newton-Raphson method according to the Jacobian matrix.

10. The method of claim 9, wherein in condition that the control mode of the each of the converters is the second type control mode and the second type control mode is the constant transformation ratio control mode, the performing the power flow calculation through the Newton-Raphson method according to the Jacobian matrix further comprises:
correcting an element Lii of the Jacobian matrix as follows:
$${L}_{ii} = - {V}_{i} {\sum }_{j ∈ i , j \neq i} {V}_{j} ( {G}_{ij} sin {θ}_{ij} - {B}_{ij} cos {θ}_{ij} ) + 2 {V}_{i}^{2} {B}_{ii} - \frac{{k}_{y}^{2} {k}_{T}^{2} {P}_{dk} {V}_{a}}{{V}_{dk} \sqrt{- {V}_{dk}^{2} + {k}_{y}^{2} {k}_{T}^{2} {V}_{i}^{2}}}$$
wherein i is a node of an AC network connected to the each of the converters, Vᵢ is a voltage amplitude of the node i, Gᵢⱼ and Bᵢⱼ are respectively a real part and an imaginary part of an admittance matrix, Vₐ is a voltage amplitude of a node connected to the each of the converters, V_{dk} is a DC power transmission voltage, P_{dk} is active power flowing into a converter k, k_{T} is a transformation ratio, k_{y} is a converter constant, θᵢⱼ is a control angle of the node i, H, N and L are block matrices of the Jacobian matrix, ΔP is the unbalance amount of the active power, ΔQ is the unbalance amount of the reactive power injection amount, and Δθ and ΔV are correction amounts of variables in an iterative process.

11. The method of claim 10, wherein the performing the power flow calculation through the Newton-Raphson method further comprises:
determining whether a calculation result of the power flow satisfies a convergence condition;
in condition that the calculation result of the power flow satisfies the convergence condition, completing the power flow calculation; and
in condition that the calculation result of the power flow does not satisfy the convergence condition, acquiring the unbalance amount of the active power and the unbalance amount of the reactive power injection amount in the power flow calculation again.

12. A terminal, comprising a display screen, a memory, a processor and computer programs stored in the memory and executable by the processor, wherein the processor is configured to, when executing the computer programs which, implement the power flow calculation method for the alternating current (AC)-direct current (DC) interconnected power system of any one of claim 1.

13. A power flow calculation method for an alternating current (AC)-direct current (DC) interconnected power system having DC hierarchical structures, comprising:
solving a conductance matrix for a DC network, and acquiring a resistance between any two of converters, or acquiring a resistance between any two of connection points of a DC power grid of hierarchical structures;
analyzing a control mode of each of the converters, and calculating a voltage and active power of each node;
calculating a reactive power injection amount into an AC power grid according to the control mode, and the voltage and the active power of the each node; and
performing power flow calculation through a Newton-Raphson method to obtain a calculation result.

14. The method of claim 13, comprising: determining part of parameters of the each node according to the control mode of the each of the converters, and constructing an equation set:
$$\begin{matrix}{I}_{dk} = {\sum }_{j = 1}^{{n}_{c}} {G}_{kj} {V}_{dj} \\ {P}_{dk} = {I}_{dk} {V}_{dk}\end{matrix} \} ,$$
wherein I_{dk} is a DC current flowing into a converter station k, and Gₖⱼ is an admittance matrix element between a node k corresponding to the converter station k and a node j; and
calculating the voltage and the active power of the each node according to a specific equation set:
$$\begin{matrix}{I}_{di 1} = {I}_{di 2} = {I}_{d} \\ \frac{{V}_{dr} - ( {V}_{di 1} + {V}_{di 2} )}{{R}_{d}} = {I}_{d}\end{matrix} \} ,$$
wherein I_{di1} is a current flowing through a high-voltage converter of the converter station in the hierarchical structures and I_{di2} is a current flowing through a low-voltage converter of the converter station in the hierarchical structures; I_{d} denotes a current flowing through the converter station, V_{dr} is a sending end voltage of the DC network; V_{di1} denotes a DC voltage of the high-voltage converter in the hierarchical structures and V_{di2} denotes a DC voltage of the low-voltage converter in the hierarchical structures; and R_{d} is a resistance of a DC line.

15. The method of claim 13, wherein an active power outputted by a single converter on a series side is proportional to a voltage ratio of the single converter.

16. The method of claim 13, comprising: calculating the reactive power injection amount into the AC power grid according to a control mode of a converter at a node, which is a control mode for a constant overlap angle, by using the following equation:
$${Q}_{idc} = \frac{{k}_{y} {P}_{idc} ( {V}_{d c}^{2} + {P}_{idc} {X}_{c} ) \times \sqrt{1 - \frac{{V}_{dk}^{4} {cos}^{2} ( {θ}_{d} )}{{{k}_{y}^{2} ( {V}_{dk}^{2} + {P}_{idc} {X}_{c} )}^{2}}}}{{V}_{dk}^{2}} ,$$
calculating the reactive power injection amount into the AC power grid according to the control mode of the converter at the node, which is a control mode for a constant transformation ratio, by using the following equation:
$${Q}_{d c} = \frac{{P}_{d c } \sqrt{- {V}_{d c} + {k}_{y}^{2} {k}_{T}^{2} {V}_{a}^{2}}}{{V}_{d c}} ,$$
and calculating an active power injection amount by calculating the state of the DC network; wherein V_{dc} is a voltage of a DC network node connected to the converter station, θ_{d} is a control angle of the converter which comprises a gating delay angle of a rectifier and an extinction advance angle of an inverter; k_{T} is a transformation ratio; X_{c} is an overlap resistance, a variable k_{y} is introduced considering an effect of an overlap angle, φᵢ is a power factor angle corresponding to active power and reactive power absorbed by the converter from an AC system; and Vₐ is a voltage amplitude of an AC network connected to the converter.

17. The method of claim 13, comprising: when the hierarchical structures are involved, completing equivalence of the power node according to a voltage ratio of a converter in the hierarchical structures.

18. The method of claim 13, wherein a specific process for calculating the reactive power injection amount into the AC power grid comprises:
in condition that a control mode of a converter corresponding to a node is a constant overlap angle control mode, calculating the reactive power injection amount by using the following equation:
$${Q}_{idc} = \frac{{k}_{y} {P}_{idc} ( {V}_{d c}^{2} + {P}_{idc} {X}_{c} ) \sqrt{1 - \frac{{V}_{dk}^{4} {cos}^{2} ( {θ}_{d} )}{{{k}_{y}^{2} ( {V}_{d c}^{2} + {P}_{idc} {X}_{c} )}^{2}}} sec ( {θ}_{d} )}{{V}_{d c}^{2}} ,$$
wherein V_{dc} is a voltage of a DC network node connected to the converter station, θ_{d} is a control angle of the converter which comprises a gating delay angle of a rectifier and an extinction advance angle of an inverter, kₜ is a transformation ratio, X_{c} is an overlap resistance, a variable k_{y} is introduced considering an effect of an overlap angle, and φᵢ is a power factor angle corresponding to active power and reactive power absorbed by the converter from an AC system; or
in condition that a control mode of a converter corresponding to a node is a constant transformation ratio control mode, calculating the reactive power injection amount by using the following equation:
$${Q}_{d c} = \frac{{P}_{d c} \sqrt{- {V}_{d c} + {k}_{y}^{2} {k}_{T}^{2} {V}_{a}^{2}}}{{V}_{d c}}$$
and calculating a derivative of the reactive power injection amount with respect to an AC voltage corresponding to the reactive power injection amount;
wherein Vₐ is a voltage amplitude of an AC network connected to the converter; and
when the hierarchical structures are involved, calculating a power effect of each of the hierarchical structures on a connection point with the AC power grid according to the following equation set:
$$\{ \begin{matrix}{P}_{idk} = {k}_{idk} {P}_{d} \\ {V}_{idk} = {k}_{idk} {V}_{d}\end{matrix}$$
wherein k_{idk} is a voltage ratio of a converter k in the hierarchical structures, P_{d} is active power of the DC network injected into the converter station, and V_{d} is a DC voltage of a node connected to the converter station, P_{idk} is active power outputted by the converter k in the hierarchical structures, and V_{idk} is a DC voltage applied across the converter k in the hierarchical structures.

19. The method of claim 13, wherein a specific process for performing the power flow calculation through the Newton-Raphson method comprises:
setting an initial value of the AC network and calculating an unbalance amount of a power flow power equation;
constructing a Jacobian matrix, in condition that the control mode of the each of the converters is a constant overlap angle control mode, a Jacobian matrix parameter of a node corresponding to the each of the converters is determined merely by an AC network parameter; and in condition that the control mode of the each of the converters is a constant transformation ratio control mode, the Jacobian matrix parameter of the node corresponding to the each of the converters is corrected after being determined by the AC network parameter; and
correcting the AC network parameter, determining whether the calculation result of the power flow satisfies a convergence condition, and in condition that the calculation result of the power flow satisfies the convergence condition, ending an iteration; in condition that the calculation result of the power flow is not satisfied with the convergence condition, repeating the specific process

20. The method of claim 19, wherein a correction mode is:
$${L}_{ii} = - {V}_{i} {\sum }_{j ∈ i , j \neq i} {V}_{j} ( {G}_{ij} sin {θ}_{ij} - {B}_{ij} cos {θ}_{ij} ) + 2 {V}_{i}^{2} {B}_{ii} - \frac{{k}_{y}^{2} {k}_{T}^{2} {P}_{d c} {V}_{a}}{{V}_{d c} \sqrt{- {V}_{d c}^{2} + {k}_{y}^{2} {k}_{T}^{2} {V}_{i}^{2}}}$$
wherein −V_{i j∈i, j≠i}Vⱼ(Gᵢⱼ sin θᵢⱼ−Bᵢⱼ cos θᵢⱼ)+2Vᵢ² Bᵢᵢ is a calculation formula of a Jacobian matrix element L in traditional pure AC power flow calculation, Vᵢ is a voltage amplitude of a node i; Gᵢⱼ and Bᵢⱼ are respectively a real part and an imaginary part of an admittance matrix; and Vₐ is a voltage amplitude of a node connected to the each of the converters and is numerically consistent with Vᵢ.
